(19) United States
(12) Patent Application Publication
(10) Pub. No.: US 2026/0068169 A1
(43) Pub. Date: Mar. 5, 2026

(54) SONOS MEMORY AND METHOD FOR MANUFACTURING THE SAME

(71) Applicant: Shanghai Huali Integrated Circuit Corporation, Shanghai (CN)

(72) Inventors: Pei WU, Shanghai (CN); Peng ZHAO, Shanghai (CN); Ruisheng QI, Shanghai (CN)

(73) Assignee: Shanghai Huali Integrated Circuit Corporation, Shanghai (CN)

(21) Appl. No.: 19/282,841

(22) Filed: Jul. 28, 2025

(30) Foreign Application Priority Data
Aug. 30, 2024 (CN) 202411215453.6

(51) Int. Cl. H10B 43/35

(52) U.S. Cl. CPC H10B 43/35

(57) ABSTRACT

Disclosed is a SONOS memory. A threshold voltage tuning region of the selection transistor presents an asymmetric structure and includes: a first threshold voltage implant region formed in a surface region of the cell well region, where a region for forming the first threshold voltage implant region is located in a region for forming the selection transistor and includes at least a region covered by a first gate structure; and a second threshold voltage implant region formed in a surface region of the cell well region, where a region for forming the second threshold voltage implant region is located in a region for forming a source region of the selection transistor and is self-aligned with a first side surface of the first gate structure. Further disclosed is a method for manufacturing a SONOS memory.

### CROSS-REFERENCES TO RELATED APPLICATIONS

This application claims priority to Chinese patent application No. CN202411215453.6, filed on Aug. 30, 2024, the disclosure of which is incorporated herein by reference in its entirety.

### TECHNICAL FIELD

The present disclosure relates to the field of semiconductor integrated circuit manufacturing, and in particular, to a silicon-oxide-nitride-oxide-silicon (SONOS) memory. The present disclosure also relates to a method for manufacturing a SONOS memory.

### BACKGROUND

FIG. 1 is a schematic structural diagram of a memory transistor of an existing SONOS memory. Unlike a memory with a floating gate structure in which charges are stored in a polysilicon floating gate, the key feature of the SONOS memory is that an ONO stack gate structure 102 is present between a semiconductor substrate 101 and a polysilicon gate 103, where the ONO stack gate structure 102 includes a silicon dioxide tunneling layer 102a (tunneling oxide), a silicon nitride memory layer 102b (oxynitride), a silicon dioxide blocking layer 102c (blocking oxide) separately from bottom to top, and charges are stored in the silicon nitride memory layer 102b in the ONO stack gate structure 102. The polysilicon gate 103 and the ONO stack gate structure 102 together form a gate structure 104. A sidewall 105 is formed on a side surface of the gate structure 104, a lightly doped drain region 106 self-aligned with the side surface of the gate structure 104 is formed in the semiconductor substrate 101 on two sides of the gate structure 104, and a heavily doped source region 107 and a heavily doped drain region 108 that are self-aligned with the corresponding sidewalls 105 are formed in the semiconductor substrate 101 on two sides of the gate structure 104, respectively.

SONOS uses a thinner tunneling oxide layer, i.e., the silicon dioxide tunneling layer 102a shown in FIG. 1, and has superior characteristics such as a fast erase speed, a low program/erase voltage required, and low power consumption. Its good compatibility with a CMOS device process makes the cost of memory IP embedding low, and it is generally recognized as one of the most industrially valuable memory technologies.

A memory cell of the 2-transistor (2T) type SONOS memory includes a memory transistor and a selection transistor, and the size thereof may be reduced continuously. By reducing the size, a program/erase voltage of the memory cell may be reduced, and a program/erase speed may be increased, thereby achieving a higher storage density. However, during process development, a micro size reduction may cause a serious gate induced drain leakage (GIDL) phenomenon. For example, with the reduction of the process node, the gate length, the gate oxide thickness, and the side gate width that are strongly correlated with the GIDL are reduced by about 20-40% at equal proportions, making the GIDL of the memory cell of the SONOS memory device 1-2 orders of magnitude larger. Therefore, a new structure or new process parameter is required to improve the memory performance of the small-sized SONOS memory.

### BRIEF SUMMARY

According to some embodiments in this application, a memory cell of the SONOS memory disclosed in this application comprising: a selection transistor and a memory transistor.

In the memory cell, a first gate structure of the selection transistor and a second gate structure of the memory transistor are both formed on a top surface of a cell well region doped with a second conductivity type, and the cell well region is formed in a selected region of a semiconductor substrate.

A threshold voltage tuning region of the selection transistor presents an asymmetric structure, and the threshold voltage tuning region includes:
a first threshold voltage implant region doped with the second conductivity type, which is formed in a surface region of a selected region of the cell well region, where a region for forming the first threshold voltage implant region is located in a region for forming the selection transistor and includes at least a region covered by the first gate structure; and
a second threshold voltage implant region doped with the second conductivity type, which is formed in a surface region of a selected region of the cell well region, where a region for forming the second threshold voltage implant region is located in a region for forming a source region of the selection transistor and is self-aligned with a first side surface of the first gate structure, and the first side surface of the first gate structure is a side surface adjacent to the source region of the selection transistor.

In some cases, the first gate structure includes a first gate dielectric layer and a first polysilicon gate stacked in sequence.

The second gate structure includes a silicon dioxide tunneling layer, a silicon nitride memory layer, a silicon dioxide blocking layer, and a second polysilicon gate stacked in sequence.

In some cases, the memory cell includes a first source-drain region, a second source-drain region, and a third source-drain region that are heavily doped with a first conductivity type.

The first source-drain region serves as a drain region of the memory transistor, the second source-drain region serves as both a source region of the memory transistor and a drain region of the selection transistor, and the third source-drain region serves as the source region of the selection transistor.

In some cases, two adjacent memory cells form a memory cell group.

In the memory cell group, two first gate structures share one third source-drain region.

The region for forming the first threshold voltage implant region includes regions for forming the two first gate structures and a region for forming the third source-drain region.

In some cases, in the memory cell group, a source line is also formed at the top of the third source-drain region.

The second threshold voltage implant regions of the two memory cells are located in surface regions of the cell well regions between the source line and the first gate structures on two sides.

The first threshold voltage implant regions of the two memory cells present an integral structure and are located in a surface region of the cell well region between two second side surfaces of the two first gate structures, and the second side surface of the first gate structure is a side surface adjacent to the drain region of the selection transistor.

In some cases, the material of the source line includes polysilicon.

In some cases, the first conductivity type is an N type, and the second conductivity type is a P type.

An implanted impurity in the cell well region includes boron or boron fluoride.

An implanted impurity in the first threshold voltage implant region includes boron or boron fluoride.

An implanted impurity in the second threshold voltage implant region includes boron or boron fluoride.

An implant dose for the cell well region is one order of magnitude less than an implant dose for the first threshold voltage implant region.

The implant dose for the first threshold voltage implant region and an implant dose for the second threshold voltage implant region are of the same order of magnitude.

According to some embodiments in this application, in a method for manufacturing a SONOS memory provided by the present disclosure, a memory cell of the SONOS memory includes a selection transistor and a memory transistor; and the method includes the following formation steps:
forming a cell well region doped with a second conductivity type in a selected region of a semiconductor substrate, where in the memory cell, regions for forming the selection transistor and the memory transistor are both located on the cell well region;
performing lithography to open a first opening region, where the first opening region defines a region for forming a first threshold voltage implant region, and the region for forming the first threshold voltage implant region is located in a region for forming the selection transistor and includes at least a region covered by a first gate structure of the selection transistor;
performing first threshold voltage implantation doped with the second conductivity type, and forming the first threshold voltage implant region in a surface region of the cell well region of the first opening region;
forming a gate structure on a top surface of the cell well region, where the gate structure includes the first gate structure of the selection transistor and a second gate structure of the memory transistor;
performing lithography to open a second opening region, where the second opening region exposes a region for forming the first gate structure and a region for forming a second threshold voltage implant region, and the region for forming the second threshold voltage implant region is located in a region for forming a source region of the selection transistor; and
performing second threshold voltage implantation doped with the second conductivity type, and forming the second threshold voltage implant region in a surface region of the cell well region in the second opening region that is not covered by the first gate structure, where the second threshold voltage implant region is self-aligned with a side surface of a source region side of the first gate structure;
the second threshold voltage implant region is located in the cell well region on a source region side of the region for forming the selection transistor and is self-aligned with a first side surface of the selection transistor, and the first side surface of the first gate structure is a side surface adjacent to the source region of the selection transistor; the first threshold voltage implant region and the second threshold voltage implant region serve as constituent parts of a threshold voltage tuning region of the selection transistor, and the threshold voltage tuning region of the selection transistor is caused to present an asymmetric structure.

In some cases, the first gate structure includes a first gate dielectric layer and a first polysilicon gate stacked in sequence.

The second gate structure includes a silicon dioxide tunneling layer, a silicon nitride memory layer, a silicon dioxide blocking layer, and a second polysilicon gate stacked in sequence.

In some cases, the first opening region and the second opening region are defined using the same mask.

In some cases, after forming the gate structure, the method further includes:

performing source-drain implantation heavily doped with a first conductivity type to form a first source-drain region, a second source-drain region, and a third source-drain region in a region for forming the memory cell.

The first source-drain region serves as a drain region of the memory transistor, the second source-drain region serves as both a source region of the memory transistor and a drain region of the selection transistor, and the third source-drain region serves as the source region of the selection transistor.

In some cases, two adjacent memory cells form a memory cell group.

In the memory cell group, two first gate structures share one third source-drain region.

The region for forming the first threshold voltage implant region includes regions for forming the two first gate structures and a region for forming the third source-drain region.

In some cases, in the memory cell group, a source line is also formed at the top of the third source-drain region.

The first opening regions of the two memory cells are combined together and are located between two second side surfaces of the two first gate structures, and the second side surface of the first gate structure is a side surface adjacent to the drain region of the selection transistor.

The second threshold voltage implant regions of the two memory cells are located in surface regions of the cell well regions between the source line and the first gate structures on two sides.

The first threshold voltage implant regions of the two memory cells present an integral structure and are located in a surface region of the cell well region between two second side surfaces of the two first gate structures.

In some cases, the material of the source line includes polysilicon.

In some cases, the first threshold voltage implant region is used to tune a channel leakage of the selection transistor, and when the channel leakage of the selection transistor exceeds a specified value, an implant dose for the first threshold voltage implant region is reduced to reduce the channel leakage of the selection transistor to be within a range of the specified value.

The second threshold voltage implant region is used to tune a threshold voltage of the selection transistor and reduce a GIDL; when the GIDL of the selection transistor increases, an implant dose for the second threshold voltage implant region is increased to reduce the GIDL of the selection transistor to be within a range of the specified value.

In some cases, when the channel leakage of the selection transistor exceeds the specified value, the method further includes: increasing an implant dose for the cell well region to reduce the channel leakage of the selection transistor to be within a range of the specified value.

In some cases, the first conductivity type is an N type, and the second conductivity type is a P type.

An implanted impurity in the cell well region includes boron or boron fluoride.

An implanted impurity in the first threshold voltage implant region includes boron or boron fluoride.

An implanted impurity in the second threshold voltage implant region includes boron or boron fluoride.

The implant dose for the cell well region is one order of magnitude less than the implant dose for the first threshold voltage implant region;

the implant dose for the first threshold voltage implant region and the implant dose for the second threshold voltage implant region are of the same order of magnitude.

The threshold voltage tuning region of the present disclosure includes the first threshold voltage implant region and the second threshold voltage implant region, which are combined to make the threshold voltage tuning region an asymmetric structure, where the second threshold voltage implant region is used to realize the asymmetric structure of the threshold voltage tuning region, and the provision of the second threshold voltage implant region may reduce an area of an overlap region between the first gate structure and the source region and a doping concentration of the first conductivity type in the overlap region, thereby reducing the GIDL of the device.

In the prior art, the asymmetric threshold voltage tuning region usually affects the threshold voltage of the selection transistor, thereby declining the channel control capability, causing the channel leakage to increase rapidly while the GIDL is reduced. Unlike the prior art, the present disclosure introduces the first threshold voltage implant region. Since the region for forming the first threshold voltage implant region includes a region covered by the first gate structure of the selection transistor, a doping concentration of a channel region at the bottom of the first gate structure may be controlled independently by adjusting the implant dose for the first threshold voltage implant region, finally improving the channel control capability of the selection transistor and effectively reducing the channel leakage.

In the present disclosure, with the blocking effect of the first gate structure on threshold voltage implantation, the present disclosure enables the opening regions before implantation in the first threshold voltage implant region and the second threshold voltage implant region to be defined using the same mask, except that the process requires performing the implantation in the first threshold voltage implant region prior to the formation of the gate structure and performing the implantation in the second threshold voltage implant region after the formation of the gate structure. Therefore, although one time of threshold voltage implantation is added in the present disclosure, there is no need to add an additional mask, thereby reducing the process cost.

In the present disclosure, the cell well region may also be used to tune the channel leakage of the selection transistor. The channel leakage of the selection transistor may be reduced by increasing the implant dose for the cell well region, thus providing a means of tuning the channel leakage of the selection transistor employing the asymmetric threshold voltage tuning region.

### BRIEF DESCRIPTION OF THE DRAWINGS

The present disclosure is further described in detail below with reference to the drawings and specific embodiments:

FIG. 1 is a schematic structural diagram of a memory transistor of an existing SONOS memory;

FIG. 2 is a schematic structural diagram of a memory cell group of a SONOS memory according to an embodiment of the present disclosure;

FIG. 3A is a schematic diagram of a device structure when a first threshold voltage implant region is formed in a method for manufacturing a SONOS memory according to an embodiment of the present disclosure; and

FIG. 3B is a schematic diagram of a device structure when a second threshold voltage implant region is formed in a method for manufacturing a SONOS memory according to an embodiment of the present disclosure.

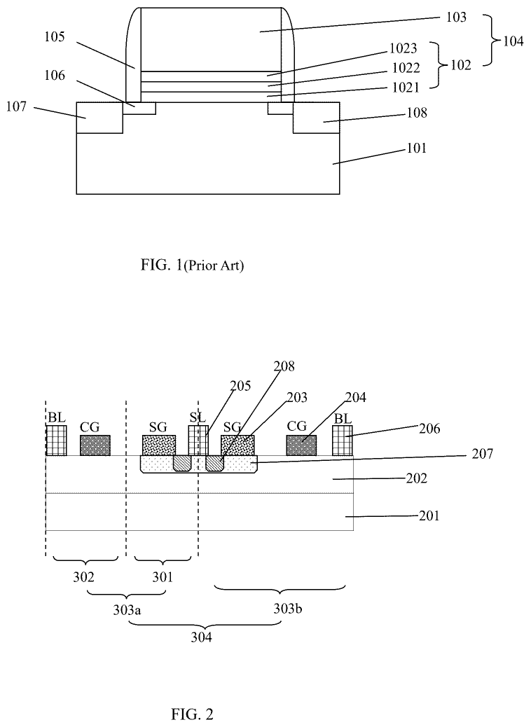

### DETAILED DESCRIPTION OF THE DISCLOSURE

FIG. 2 is a schematic structural diagram of a memory cell group of a SONOS memory according to an embodiment of the present disclosure. A memory cell of the SONOS memory according to this embodiment of the present disclosure includes a selection transistor and a memory transistor. Two memory cells are shown in FIG. 2, and regions for forming the two memory cells are regions 303a and 303b, respectively.

The two memory cells have the same structure. Taking the memory cell in the region 303a as an example, a region for forming the selection transistor is a region 301, and a region for forming the memory transistor is a region 302.

In the memory cell, a first gate structure 203 of the selection transistor and a second gate structure 204 of the memory transistor are both formed on a top surface of a cell well region 202 doped with a second conductivity type, and the cell well region 202 is formed in a selected region of a semiconductor substrate 201.

In FIG. 2, the first gate structure 203 is denoted by SG, and the second gate structure is denoted by CG.

In this embodiment of the present disclosure, the first gate structure 203 includes a first gate dielectric layer (not shown) and a first polysilicon gate (not shown) stacked in sequence.

The second gate structure 204 includes a silicon dioxide tunneling layer (not shown), a silicon nitride memory layer (not shown), a silicon dioxide blocking layer (not shown), and a second polysilicon gate (not shown) stacked in sequence.

A threshold voltage tuning region of the selection transistor presents an asymmetric structure, and the threshold voltage tuning region includes:
a first threshold voltage implant region 207 doped with the second conductivity type, which is formed in a surface region of a selected region of the cell well region 202, where a region for forming the first threshold voltage implant region 207 is located in a region for forming the selection transistor and includes at least a region covered by the first gate structure 203; and
a second threshold voltage implant region 208 doped with the second conductivity type, which is formed in a surface region of a selected region of the cell well region 202, where a region for forming the second threshold voltage implant region 208 is located in a region for forming a source region of the selection transistor and is self-aligned with a first side surface of the first gate structure 203, and the first side surface of the first gate structure 203 is a side surface adjacent to the source region of the selection transistor.

In this embodiment of the present disclosure, the memory cell includes a first source-drain region (not shown), a second source-drain region (not shown), and a third source-drain region (not shown) that are heavily doped with a first conductivity type.

The first source-drain region serves as a drain region of the memory transistor, the second source-drain region serves as both a source region of the memory transistor and a drain region of the selection transistor, and the third source-drain region serves as the source region of the selection transistor.

In FIG. 2, in the region 303a, the first source-drain region is formed on the left side of the second gate structure 204 in the region 302 in a self-aligned manner, and the top of the first source-drain region is connected to a bit line (BL) through a connection structure 206.

The second source-drain region is formed between the first gate structure 203 and the second gate structure 204 in a self-aligned manner.

In the region 303a, the third source-drain region is formed on the right side of the first gate structure 203 in the region 301 in a self-aligned manner; and the top of the third source-drain region is connected to a source line 205. The source line 205 is denoted by SL.

Referring to FIG. 2, two adjacent memory cells form a memory cell group.

In the memory cell group, two first gate structures 203 share one third source-drain region. The source line 205 at the top of the third source-drain region is also shared.

Referring to FIG. 2, in this embodiment of the present disclosure, the region for forming the first threshold voltage implant region 207 includes regions for forming the two first gate structures 203 and a region for forming the third source-drain region.

The second threshold voltage implant regions 208 of the two memory cells are located in surface regions of the cell well regions 202 between the source line 205 and the first gate structures 203 on two sides.

The first threshold voltage implant regions 207 of the two memory cells present an integral structure and are located in a surface region of the cell well region 202 between two second side surfaces of the two first gate structures 203, and the second side surface of the first gate structure 203 is a side surface adjacent to the drain region of the selection transistor.

The positions of the first threshold voltage implant region 207 and the second threshold voltage implant region 208 in FIG. 2 are set such that both can be defined using the same mask. It is only necessary to perform ion implantation in the first threshold voltage implant region 207 before the formation of the gate structure and perform ion implantation in the second threshold voltage implant region 208 after the formation of the gate structure. The gate structure herein includes the first gate structure 203 and the second gate structure 204. In this embodiment of the present disclosure, the material of the source line 205 includes polysilicon. The material of the connection structure 206 also includes polysilicon. In this way, the ion implantation in the second threshold voltage implant region 208 is performed after the formation of all of the gate structure, the source line 205, and the connection structure 206.

In this embodiment of the present disclosure, a channel conductivity type is an N type, the memory transistor and the selection transistor are both N type devices, the first conductivity type is an N type, and the second conductivity type is a P type. In other embodiments, the channel conductivity type may be a P type, the first conductivity type may be a P type, and the second conductivity type may be an N type.

The following description is made with an example of the channel conductivity type as being the N type:

An implanted impurity in the cell well region 202 includes boron or boron fluoride.

An implanted impurity in the first threshold voltage implant region 207 includes boron or boron fluoride.

An implanted impurity in the second threshold voltage implant region 208 includes boron or boron fluoride.

An implant dose for the cell well region 202 is one order of magnitude less than an implant dose for the first threshold voltage implant region 207.

The implant dose for the first threshold voltage implant region 207 and an implant dose for the second threshold voltage implant region 208 are of the same order of magnitude.

In some embodiments, the order of magnitude of the implant dose for the cell well region 202 is 10⁻¹² cm⁻², for example, the implant dose for the cell well region 202 is about 3.6E12 cm⁻².

The order of magnitude of the implant dose for the first threshold voltage implant region 207 is 10-13 cm⁻².

The threshold voltage tuning region of this embodiment of the present disclosure includes the first threshold voltage implant region 207 and the second threshold voltage implant region 208, which are combined to make the threshold voltage tuning region an asymmetric structure, where the second threshold voltage implant region 208 is used to realize the asymmetric structure of the threshold voltage tuning region, and the provision of the second threshold voltage implant region 208 may reduce an area of an overlap region between the first gate structure 203 and the source region and a doping concentration of the first conductivity type in the overlap region, thereby reducing the GIDL of the device.

In the prior art, the asymmetric threshold voltage tuning region usually affects the threshold voltage of the selection transistor, thereby declining the channel control capability, causing the channel leakage to increase rapidly while the GIDL is reduced. Unlike the prior art, this embodiment of the present disclosure introduces the first threshold voltage implant region 207. Since the region for forming the first threshold voltage implant region 207 includes a region covered by the first gate structure 203 of the selection transistor, a doping concentration of a channel region at the bottom of the first gate structure 203 may be controlled independently by adjusting the implant dose for the first threshold voltage implant region 207, finally improving the channel control capability of the selection transistor and effectively reducing the channel leakage.

In this embodiment of the present disclosure, with the blocking effect of the first gate structure 203 on threshold voltage implantation, the present disclosure enables the opening regions before implantation in the first threshold voltage implant region 207 and the second threshold voltage implant region 208 to be defined using the same mask, except that the process requires performing the implantation in the first threshold voltage implant region 207 prior to the formation of the gate structure and performing the implantation in the second threshold voltage implant region 208 after the formation of the gate structure. Therefore, although one time of threshold voltage implantation is added in this embodiment of the present disclosure, there is no need to add an additional mask, thereby reducing the process cost.

In this embodiment of the present disclosure, the cell well region 202 may also be used to tune the channel leakage of the selection transistor. The channel leakage of the selection transistor may be reduced by increasing the implant dose for the cell well region 202, thus providing a means of tuning the channel leakage of the selection transistor employing the asymmetric threshold voltage tuning region.

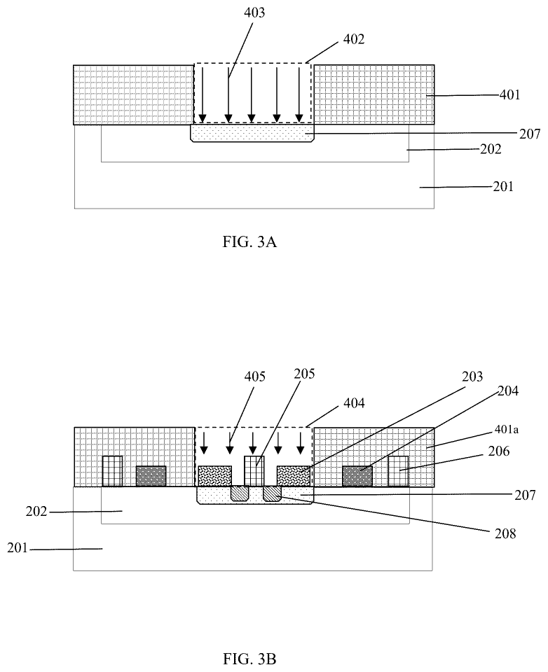

FIG. 3A is a schematic diagram of a device structure when a first threshold voltage implant region is formed in a method for manufacturing a SONOS memory according to an embodiment of the present disclosure. FIG. 3B is a schematic diagram of a device structure when a second threshold voltage implant region is formed in a method for manufacturing a SONOS memory according to an embodiment of the present disclosure. In the method for manufacturing a SONOS memory provided by this embodiment of the present disclosure, a memory cell of the SONOS memory includes a selection transistor and a memory transistor; and the method includes the following formation steps:

Step S101: Referring to FIG. 3A, a cell well region 202 doped with a second conductivity type is formed in a selected region of a semiconductor substrate 201, where in the memory cell, regions for forming the selection transistor and the memory transistor are both located on the cell well region 202.

Step S102: Referring to FIG. 3A, lithography is performed to open a first opening region 402, that is, lithography is performed to form a photoresist pattern 401, where the opened first opening region 402 is present in the photoresist pattern 401, the first opening region 402 defines a region for forming a first threshold voltage implant region 207, and the region for forming the first threshold voltage implant region 207 is located in a region for forming the selection transistor and includes at least a region covered by a first gate structure 203 of the selection transistor.

Step S103: Referring to FIG. 3A, first threshold voltage implantation doped with the second conductivity type is performed, and the first threshold voltage implant region 207 is formed in a surface region of the cell well region 202 of the first opening region 402. The first threshold voltage implantation is as shown by an arrowed line 403.

Step S104: Referring to FIG. 3B, a gate structure is formed on a top surface of the cell well region 202, where the gate structure includes the first gate structure 203 of the selection transistor and a second gate structure 204 of the memory transistor.

In the method of this embodiment of the present disclosure, the first gate structure 203 includes a first gate dielectric layer and a first polysilicon gate stacked in sequence.

The second gate structure 204 includes a silicon dioxide tunneling layer, a silicon nitride memory layer, a silicon dioxide blocking layer, and a second polysilicon gate stacked in sequence.

Step S105: Referring to FIG. 3B, lithography is performed to open a second opening region 404, that is, lithography is performed to form a photoresist pattern 401a, where the opened second opening region 404 is present in the photoresist pattern 401a, the second opening region 404 exposes a region for forming the first gate structure 203 and a region for forming a second threshold voltage implant region 208, and the region for forming the second threshold voltage implant region 208 is located in a region for forming a source region of the selection transistor.

In the method of this embodiment of the present disclosure, the first opening region 402 and the second opening region 404 are defined using the same mask.

Step S106: Referring to FIG. 3B, second threshold voltage implantation doped with the second conductivity type is performed, and the second threshold voltage implant region 208 is formed in a surface region of the cell well region 202 in the second opening region 404 that is not covered by the first gate structure 203, where the second threshold voltage implant region 208 is self-aligned with a side surface of a source region side of the first gate structure 203.

The second threshold voltage implant region 208 is located in the cell well region 202 on a source region side of the region for forming the selection transistor and is self-aligned with a first side surface of the selection transistor, and the first side surface of the first gate structure 203 is a side surface adjacent to the source region of the selection transistor.

The first threshold voltage implant region 207 and the second threshold voltage implant region 208 serve as constituent parts of a threshold voltage tuning region of the selection transistor, and the threshold voltage tuning region of the selection transistor is caused to present an asymmetric structure.

After forming the gate structure, the method further includes:

performing source-drain implantation heavily doped with a first conductivity type to form a first source-drain region, a second source-drain region, and a third source-drain region in a region for forming the memory cell. The first source-drain region, the second source-drain region, and the third source-drain region are formed between the corresponding gate structures in a self-aligned manner.

The first source-drain region serves as a drain region of the memory transistor, the second source-drain region serves as both a source region of the memory transistor and a drain region of the selection transistor, and the third source-drain region serves as the source region of the selection transistor.

Referring to FIG. 2, two adjacent memory cells form a memory cell group.

In the memory cell group, two first gate structures 203 share one third source-drain region.

The region for forming the first threshold voltage implant region 207 includes regions for forming the two first gate structures 203 and a region for forming the third source-drain region.

In the method of this embodiment of the present disclosure, in the memory cell group, a source line 205 is also formed at the top of the third source-drain region.

The top of the first source-drain region is connected to a bit line through a connection structure 206.

The material of the source line 205 includes polysilicon. The material of the connection structure 206 includes polysilicon.

The first opening regions 402 of the two memory cells are combined together and are located between two second side surfaces of the two first gate structures 203, and the second side surface of the first gate structure 203 is a side surface adjacent to the drain region of the selection transistor.

The second threshold voltage implant regions 208 of the two memory cells are located in surface regions of the cell well regions 202 between the source line 205 and the first gate structures 203 on two sides.

The first threshold voltage implant regions 207 of the two memory cells present an integral structure and are located in a surface region of the cell well region 202 between two second side surfaces of the two first gate structures 203.

In the method of this embodiment of the present disclosure, the first threshold voltage implant region 207 is used to tune a channel leakage of the selection transistor, and when the channel leakage of the selection transistor exceeds a specified value, an implant dose for the first threshold voltage implant region 207 is reduced to reduce the channel leakage of the selection transistor to be within a range of the specified value.

The second threshold voltage implant region 208 is used to tune a threshold voltage of the selection transistor and reduce a GIDL; when the GIDL of the selection transistor increases, an implant dose for the second threshold voltage implant region 208 is increased to reduce the GIDL of the selection transistor to be within a range of the specified value.

When the channel leakage of the selection transistor exceeds the specified value, the method further includes: increasing an implant dose for the cell well region 202 to reduce the channel leakage of the selection transistor to be within a range of the specified value.

In the method of this embodiment of the present disclosure, a channel conductivity type is an N type, the memory transistor and the selection transistor are both N type devices, the first conductivity type is an N type, and the second conductivity type is a P type. In the method of other embodiments, the channel conductivity type may be a P type, the first conductivity type may be a P type, and the second conductivity type may be an N type.

The following description is made with an example of the channel conductivity type as being the N type:

An implanted impurity in the cell well region 202 includes boron or boron fluoride.

An implanted impurity in the first threshold voltage implant region 207 includes boron or boron fluoride.

An implanted impurity in the second threshold voltage implant region 208 includes boron or boron fluoride.

An implant dose for the cell well region 202 is one order of magnitude less than an implant dose for the first threshold voltage implant region 207.

The implant dose for the first threshold voltage implant region 207 and an implant dose for the second threshold voltage implant region 208 are of the same order of magnitude.

In the method of some embodiments, the order of magnitude of the implant dose for the cell well region 202 is 10⁻¹² cm⁻², for example, the implant dose for the cell well region 202 is about 3.6E12 cm⁻².

The order of magnitude of the implant dose for the first threshold voltage implant region 207 is 10-13 cm⁻².

The method for making a SONOS memory device or flash device of this embodiment of the present disclosure requires no additional development process and no additional mask, where after polysilicon (poly), i.e., after the formation of the gate structure, a threshold voltage tuning region (RVTN) formation process and an asymmetric ion implantation (IMP) condition are used to adjust the threshold voltage (Vt) of the selection transistor and reduce the GIDL.

However, the GIDL has a relative effect with respect to the channel leakage: under the asymmetric condition, the GIDL is effectively suppressed while the channel leakage is increased rapidly. Accordingly, in this embodiment of the present disclosure, an RVTN mask is reused after a well, i.e., the cell well region (CPW) is formed, and the Vt IMP implant dose is increased, so as to adjust the doping concentration of the channel region, thereby improving the channel control capability and effectively reducing the channel leakage by

Further, this embodiment of the present disclosure may also increase the boron (B) IMP dose of the CPW, thereby reducing the channel leakage without increasing Vt of the selection transistor.

This embodiment of the present disclosure constructs an asymmetric solution through RVTN reuse and IMP dose tuning, which can reduce the GIDL due to a size reduction during process development by about 25%, and reduce the leakage current with a small impact on the source-drain saturation current (Idsat), achieving a balance between leakage improvement and performance optimization. Further, the method of this embodiment of the present disclosure may be developed based on an existing platform, without additional process development and masks, which saves the cost, is stable and controllable, and is suitable for mass production.

In a manufacturing process for the memory of this embodiment of the present disclosure, an RVTN is opened after the well is formed, and the IMP dose is increased, so as to adjust the concentration in the channel and improve the channel control capability, thereby effectively reducing the channel leakage; the RVTN mask is reused after the poly, and through asymmetric IMP, Vt of the selection transistor is adjusted while GIDL is reduced. Meanwhile, the CPW B IMP dose is increased to reduce the channel leakage.

The present disclosure is described in detail above through specific embodiments, which, however, do not impose limitations to the present disclosure. Without departing from the principle of the present disclosure, a person skilled in the art may also made many other deformations and improvements, which should also be considered as the protection scope of the present disclosure.

What is claimed is:

1. A SONOS memory, wherein a memory cell of the SONOS memory comprises a selection transistor and a memory transistor;
in the memory cell, a first gate structure of the selection transistor and a second gate structure of the memory transistor are both formed on a top surface of a cell well region doped with a second conductivity type, and the cell well region is formed in a semiconductor substrate;
a threshold voltage tuning region of the selection transistor presents an asymmetric structure, and the threshold voltage tuning region comprises:
a first threshold voltage implant region doped with the second conductivity type, which is formed in a surface region of the cell well region, wherein a region for forming the first threshold voltage implant region is located in a region for forming the selection transistor and comprises at least a region covered by the first gate structure; and
a second threshold voltage implant region doped with the second conductivity type, which is formed in a surface region of the cell well region, wherein a region for forming the second threshold voltage implant region is located in a region for forming a source region of the selection transistor and is self-aligned with a first side surface of the first gate structure, and the first side surface of the first gate structure is a side surface adjacent to the source region of the selection transistor.

2. The SONOS memory according to claim 1, wherein the first gate structure comprises a first gate dielectric layer and a first polysilicon gate stacked in sequence;
the second gate structure comprises a silicon dioxide tunneling layer, a silicon nitride memory layer, a silicon dioxide blocking layer, and a second polysilicon gate stacked in sequence.

3. The SONOS memory according to claim 2, wherein the memory cell comprises a first source-drain region, a second source-drain region, and a third source-drain region that are heavily doped with a first conductivity type;
the first source-drain region serves as a drain region of the memory transistor, the second source-drain region serves as both a source region of the memory transistor and a drain region of the selection transistor, and the third source-drain region serves as the source region of the selection transistor.

4. The SONOS memory according to claim 3, wherein two adjacent memory cells form a memory cell group;
in the memory cell group, two first gate structures share one third source-drain region;
the region for forming the first threshold voltage implant region comprises regions for forming the two first gate structures and a region for forming the third source-drain region.

5. The SONOS memory according to claim 4, wherein in the memory cell group, a source line is also formed at the top of the third source-drain region;
the second threshold voltage implant regions of the two memory cells are located in surface regions of the cell well regions between the source line and the first gate structures on two sides;
the first threshold voltage implant regions of the two memory cells present an integral structure and are located in a surface region of the cell well region between two second side surfaces of the two first gate structures, and the second side surface of the first gate structure is a side surface adjacent to the drain region of the selection transistor.

6. The SONOS memory according to claim 5, wherein the material of the source line comprises polysilicon.

7. The SONOS memory according to claim 5, wherein the first conductivity type is an N type, and the second conductivity type is a P type;
an implanted impurity in the cell well region comprises boron or boron fluoride;
an implanted impurity in the first threshold voltage implant region comprises boron or boron fluoride;
an implanted impurity in the second threshold voltage implant region comprises boron or boron fluoride;
an implant dose for the cell well region is one order of magnitude less than an implant dose for the first threshold voltage implant region;
the implant dose for the first threshold voltage implant region and an implant dose for the second threshold voltage implant region are of the same order of magnitude.

8. A method for manufacturing a SONOS memory, wherein a memory cell of the SONOS memory comprises a selection transistor and a memory transistor; the method comprises the following formation steps:
forming a cell well region doped with a second conductivity type in a semiconductor substrate, wherein in the memory cell, regions for forming the selection transistor and the memory transistor are both located on the cell well region;
performing lithography to open a first opening region, wherein the first opening region defines a region for forming a first threshold voltage implant region, and the region for forming the first threshold voltage implant region is located in a region for forming the selection transistor and comprises at least a region covered by a first gate structure of the selection transistor;
performing first threshold voltage implantation doped with the second conductivity type, and forming the first threshold voltage implant region in a surface region of the cell well region of the first opening region;
forming a gate structure on a top surface of the cell well region, wherein the gate structure comprises the first gate structure of the selection transistor and a second gate structure of the memory transistor;
performing lithography to open a second opening region, wherein the second opening region exposes a region for forming the first gate structure and a region for forming a second threshold voltage implant region, and the region for forming the second threshold voltage implant region is located in a region for forming a source region of the selection transistor; and
performing second threshold voltage implantation doped with the second conductivity type, and forming the second threshold voltage implant region in a surface region of the cell well region in the second opening region that is not covered by the first gate structure, wherein the second threshold voltage implant region is located in the cell well region on a source region side of the region for forming the selection transistor and is self-aligned with a first side surface of the selection transistor, and the first side surface of the first gate structure is a side surface adjacent to the source region of the selection transistor;
the first threshold voltage implant region and the second threshold voltage implant region serve as constituent parts of a threshold voltage tuning region of the selection transistor, and the threshold voltage tuning region of the selection transistor is caused to present an asymmetric structure.

9. The method for manufacturing a SONOS memory according to claim 8, wherein the first gate structure comprises a first gate dielectric layer and a first polysilicon gate stacked in sequence;
the second gate structure comprises a silicon dioxide tunneling layer, a silicon nitride memory layer, a silicon dioxide blocking layer, and a second polysilicon gate stacked in sequence.

10. The method for manufacturing a SONOS memory according to claim 9, wherein the first opening region and the second opening region are defined using the same mask.

11. The method for manufacturing a SONOS memory according to claim 10, after forming the gate structure, further comprising:
performing source-drain implantation heavily doped with a first conductivity type to form a first source-drain region, a second source-drain region, and a third source-drain region in a region for forming the memory cell, wherein
the first source-drain region serves as a drain region of the memory transistor, the second source-drain region serves as both a source region of the memory transistor and a drain region of the selection transistor, and the third source-drain region serves as the source region of the selection transistor.

12. The method for manufacturing a SONOS memory according to claim 11, wherein two adjacent memory cells form a memory cell group;
in the memory cell group, two first gate structures share one third source-drain region;
the region for forming the first threshold voltage implant region comprises regions for forming the two first gate structures and a region for forming the third source-drain region.

13. The method for manufacturing a SONOS memory according to claim 12, wherein in the memory cell group, a source line is also formed at the top of the third source-drain region;
the first opening regions of the two memory cells are combined together and are located between two second side surfaces of the two first gate structures, and the second side surface of the first gate structure is a side surface adjacent to the drain region of the selection transistor;
the second threshold voltage implant regions of the two memory cells are located in surface regions of the cell well regions between the source line and the first gate structures on two sides;
the first threshold voltage implant regions of the two memory cells present an integral structure and are located in a surface region of the cell well region between two second side surfaces of the two first gate structures.

14. The method for manufacturing a SONOS memory according to claim 13, wherein the material of the source line comprises polysilicon.

15. The method for manufacturing a SONOS memory according to claim 14, wherein the first threshold voltage implant region is used to tune a channel leakage of the selection transistor, and when the channel leakage of the selection transistor exceeds a specified value, an implant dose for the first threshold voltage implant region is reduced to reduce the channel leakage of the selection transistor to be within a range of the specified value;
the second threshold voltage implant region is used to tune a threshold voltage of the selection transistor and reduce a GIDL; when the GIDL of the selection transistor increases, an implant dose for the second threshold voltage implant region is increased to reduce the GIDL of the selection transistor to be within a range of the specified value.

16. The method for manufacturing a SONOS memory according to claim 15, when the channel leakage of the selection transistor exceeds the specified value, further comprising: increasing an implant dose for the cell well region to reduce the channel leakage of the selection transistor to be within a range of the specified value.

17. The method for manufacturing a SONOS memory according to claim 16, wherein the first conductivity type is an N type, and the second conductivity type is a P type;
an implanted impurity in the cell well region comprises boron or boron fluoride;
an implanted impurity in the first threshold voltage implant region comprises boron or boron fluoride;
an implanted impurity in the second threshold voltage implant region comprises boron or boron fluoride;
the implant dose for the cell well region is one order of magnitude less than the implant dose for the first threshold voltage implant region;
the implant dose for the first threshold voltage implant region and the implant dose for the second threshold voltage implant region are of the same order of magnitude.
